(19) United States
(12) Patent Application Publication
(10) Pub. No.: US 2025/0314739 A1
(43) Pub. Date: Oct. 9, 2025

(54) ARRANGEMENT WITH A HOLDER AND A HOUSING FOR AN ELECTRONIC ASSEMBLY, IN PARTICULAR FOR A RADAR SENSOR, ASSEMBLY WITH SUCH AN ARRANGEMENT, AND METHOD FOR PRODUCING SUCH AN ARRANGEMENT

(71) Applicant: HELLA GMBH & CO. KGAA, Lippstadt (DE)

(72) Inventors: Thomas Schmitz, Lippstadt (DE); Hans-Georg Voelker, Moehnesee (DE)

(21) Appl. No.: 19/079,013

(22) Filed: Mar. 13, 2025

(30) Foreign Application Priority Data
Apr. 9, 2024 (DE) 102024109808.2

(51) Int. Cl. G01S 7/02; H01Q 1/42; H05K 7/20; H05K 9/00

(52) U.S. Cl. CPC G01S 7/027; H01Q 1/42; H05K 9/0056; H05K 7/20409

(57) ABSTRACT

The invention relates to an arrangement with a holder and a housing for an electronic assembly, in particular for a radar sensor, and an assembly with such an arrangement, in particular the radar sensor. Further components of the electronic assembly can be attached to the holder, for example a circuit carrier with an electronic circuit arrangement. The housing or a part of the housing is molded onto the holder, and the holder has an outer contour which is wholly or partially complementary to an inner contour of the housing, in particular of a part of the housing.

### CROSS-REFERENCE TO RELATED APPLICATIONS

The present application claims the benefit of German Patent Application No. 10-2024-109-808.2, filed Apr. 9, 2024, the disclosure of which is incorporated by reference.

### FIELD OF THE INVENTION

The invention relates to an arrangement with a holder and a housing for an electronic assembly, in particular for a radar sensor, and an assembly with such an arrangement, in particular a radar sensor. The invention further relates to a method for producing such an arrangement.

### BACKGROUND OF THE INVENTION

Radar sensors with plastic housings are known from the prior art, in which the heat dissipation of an electronic circuit arrangement of the radar sensor takes place via a metal component holder. The housing and the holder are manufactured individually and joined and bonded together in the production of the radar sensors. Adhesive surfaces or points and contact surfaces or contact points between the housing and the holder in the area of the housing base are created during joining. In the known radar sensors, these surfaces or points are substantially thermally effective in removing the heat from the electronic circuit arrangement, since only in the area of the base is there an adhesive surface or adhesive points between the housing and holder and thus a contact surface or contact points between the housing and holder that provide sufficient heat conduction. In particular, only a small amount of heat is transferred via the side walls of the plastic housing, as the air gaps present for tolerance reasons and the low thermal conductivity of plastics mean that essentially no heat is transferred via the side walls of the housing. This creates areas with a high temperature on the base of the housing when the sensors are in operation.

### SUMMARY OF THE INVENTION

The invention is based on the object of avoiding areas with high temperatures during operation of the electronic assembly. At the same time, producing the assembly should be simplified. According to the invention, this object is achieved by an arrangement which has a housing of the assembly and, as a holder, a metal part to which further components of the electronic assembly, for example a circuit carrier with an electronic circuit arrangement, can be mounted. The housing is molded onto the holder and the holder has an outer contour which is wholly or partially complementary to an inner contour of the housing. This allows a large contact surface to be achieved between the holder and the housing. The contact surfaces of the housing can include the side walls and the base in particular.

In particular, the housing may have protruding elements that surround an edge of the holder. Such an edge of the holder can be provided at a hole in the holder. The protruding elements of the housing could rub through the hole and reach behind the edge of the hole.

By embedding the holder in the housing, a large contact surface is produced between the holder and the housing, which facilitates heat transfer from the holder to the housing, i.e. from one part of the arrangement to the other part of the arrangement. The complementary design of the outer contour of the holder and the inner contour of the housing creates a large contact surface between the holder and the housing, which facilitates the transport of goods from the holder into the housing. This contact surface can also comprise the side walls.

The metal part can be an aluminum die-cast part, a bent sheet metal part or a deep-drawn sheet metal part. The housing can preferably be produced from the plastic polybutylene terephthalate (PBT). The plastic can be reinforced with glass fibers. The proportion of glass fibers can be 20%. The metal part can be completely or partially overmolded with the plastic to produce the arrangement.

The holder can have mounting structures for a circuit carrier. For example, flaps, domes or similar could be exhibited. Holes, in particular threaded holes, can also be provided as mounting structures.

The holder can form an electromagnetic shield for the further components of the electronic assembly, in particular for an electronic circuit arrangement of the assembly.

An electronic assembly with an arrangement according to the invention may have an electronic circuit arrangement arranged in the housing and in the holder and mounted on the holder. The circuit arrangement can be arranged in the holder to the extent necessary for electromagnetic shielding of the circuit arrangement.

The assembly can have a circuit carrier on which the circuit arrangement is arranged.

The assembly according to the invention can be a radar sensor. The housing of the radar sensor can have a radome as a housing cover. Furthermore, a radar sensor according to the invention may have an antenna, in particular a waveguide antenna.

The method of producing an arrangement described above comprises at least the following steps:
providing the holder with an outer contour; and
overmolding the holder with a plastic, at least in some areas, so that the inner contour is formed during overmolding, wherein the housing of the arrangement is at least partially formed by overmolding.

The outer contour is advantageously produced by a forming process or by extrusion molding the holder. Further advantageous is the overmolding with an injection molding method. The method makes it particularly easy to produce the arrangement.

Advantageously, further parts of the housing are produced by an injection molding method and firmly connected to the arrangement so that the housing is formed.

### BRIEF DESCRIPTION OF THE DRAWINGS

An exemplary embodiment of a radar sensor according to the invention is described in more detail with reference to the drawings. In the drawings:

FIG. 1 is a perspective representation of the radar sensor;

FIG. 2 is a perspective representation of an arrangement according to the invention consisting of a housing and a holder of the radar sensor;

FIG. 3 is is a top view of the arrangement; and

FIG. 4 is a cut through the arrangement according to line III-III in FIG. 3.

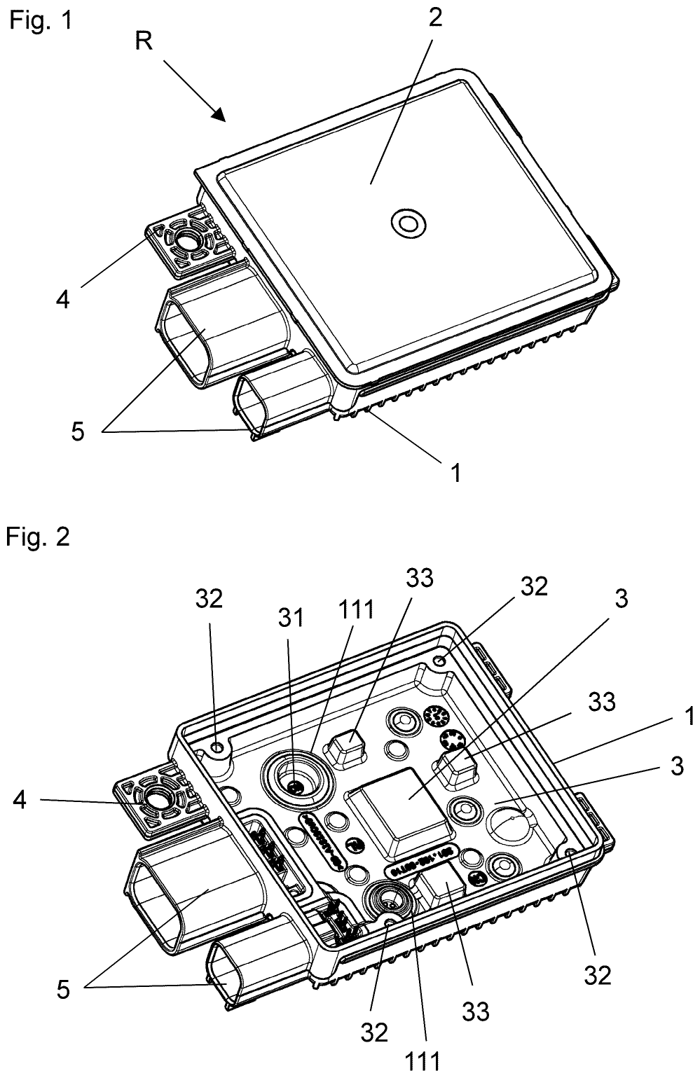

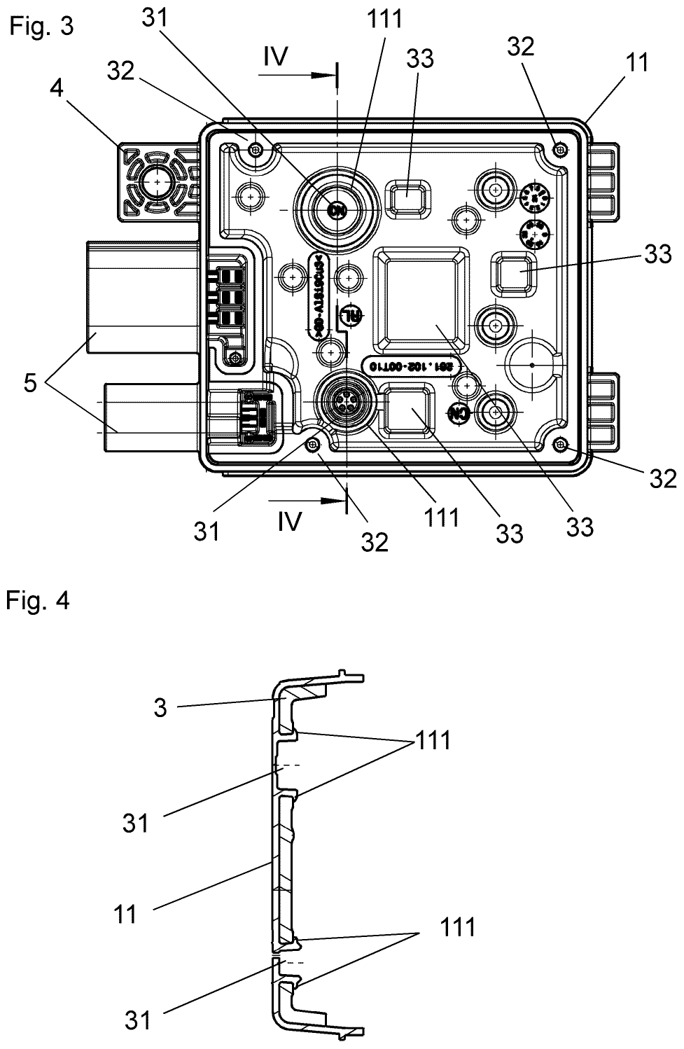

### DETAILED DESCRIPTION OF THE CURRENT EMBODIMENT

The radar sensor R according to the invention has a housing 1 with a housing shell 11 and a radome as housing cover 2. An antenna of the radar sensor R is located under the radome. This antenna is connected to an electronic circuit arrangement. This circuit arrangement is arranged on a circuit carrier, namely a circuit board.

A mounting bracket 4 and sockets 5 for plug connections are provided on the housing 1.

The circuit carrier is mounted on a holder 3. For this purpose, mounting structures 32 for a circuit carrier are provided on the holder 3. The holder 3 surrounds the circuit carrier in lateral directions and in the direction of the base. Raised structures 33 of the holder 3 form contact surfaces for areas of the circuit carrier where heat is generated to a particular extent and must be dissipated into the holder 3.

The holder 3 is a metal part. The holder 3 is advantageously made of aluminum.

The outer contour of the holder 3 is complementary to the inner contour of the housing 1, more specifically the housing lower part 11.

The holder 3 is not only used for mounting the circuit carrier for the circuit arrangement. Rather, it also forms a heat sink for heat dissipation in the circuit arrangement. Heat can be dissipated via the fixing points of the circuit carrier on the metal part. Furthermore, the holder 3 also forms a shield for electromagnetic radiation, which is why the holder 3 in particular at least partially surrounds the circuit carrier.

There is a large contact surface between the housing lower part 11 and the holder 3, so that despite the inherently poor thermal conductivity of the plastic of the housing lower part 11 compared to that of the holder 3, a sufficient amount of heat can be transported from the circuit arrangement via the holder 3 into the housing 1. Due to the complementary design of the outer contour of the holder 3 and the inner contour of the housing 1, the large contact surface is produced between the holder 3 and the housing 1, via which heat can be dissipated from the holder 3 into the housing 1.

To produce the large contact surface without any play between the holder 3 and the housing 1, the housing lower part 11 is molded onto the holder 3. The holder 3 has holes 31 through which protruding elements 111 of the housing lower part 11 project. These protruding elements 111 of the housing lower part 11 engage behind one edge of the holes 31, so that a form-fit connection is established between the housing 1 and the holder 3.

### LIST OF REFERENCE NUMERALS

1 housing
11 housing lower part
111 fastening elements
2 housing cover
3 holder
31 holes of the holder
32 mounting structures
33 structures for heat dissipation
4 mounting bracket
5 sockets
R radar sensor

The above description is that of current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. An arrangement for an electronic assembly, the arrangement comprising:
a housing; and
a holder, to which an electronic circuit is mounted, wherein at least a portion of the housing is molded onto the holder, and wherein the holder has an outer contour which is wholly or partially complementary to an inner contour of the housing.

2. The arrangement of claim 1, wherein the holder is a die-cast aluminum part, a bent sheet metal part, or a deep-drawn sheet metal part.

3. The arrangement of claim 1, wherein the holder has mounting structures for the electronic circuit.

4. The arrangement of claim 1, wherein the holder forms an electromagnetic shield for further components of the electronic circuit.

5. An electronic assembly comprising the arrangement of claim 1, wherein the electronic circuit is arranged in the housing and on and in the holder.

6. The electronic assembly of claim 5, wherein the electronic assembly has a circuit board on which the electronic circuit is arranged.

7. The electronic assembly of claim 5, wherein the electronic assembly is a radar sensor.

8. The radar sensor of claim 7, wherein the housing of the radar sensor has a radome as a housing cover.

9. The radar sensor of claim 7, wherein the radar sensor has a waveguide antenna.

10. A method of producing the arrangement of claim 1, comprising:
providing the holder with the outer contour; and
overmolding the holder with a plastic, so that the inner contour is formed during overmolding, wherein the housing of the arrangement of claim 1 is at least partially formed by the overmolding.
